(19) United States
(12) Patent Application Publication
(10) Pub. No.: US 2025/0079295 A1
(43) Pub. Date: Mar. 6, 2025

(54) INTERCONNECTION STRUCTURE

(71) Applicant: TAIWAN SEMICONDUCTOR MANUFACTURING COMPANY, LTD., Hsinchu (TW)

(72) Inventors: Chia-Chen LEE, Hsinchu (TW); Chia-Tien WU, Hsinchu (TW); Wei-Chen CHU, Hsinchu (TW)

(73) Assignee: TAIWAN SEMICONDUCTOR MANUFACTURING COMPANY, LTD., Hsinchu (TW)

(21) Appl. No.: 18/461,328

(22) Filed: Sep. 5, 2023

(51) Int. Cl. H01L 23/522; H01L 21/768

(52) U.S. Cl. CPC H01L 23/5226; H01L 21/76807; H01L 21/76832; H01L 21/76877

(57) ABSTRACT

An interconnection structure includes a substrate, a first dielectric layer over the substrate, a second dielectric layer over the first dielectric layer, a third dielectric layer over the second dielectric layer, and a hyper via. The first dielectric layer is formed with a first metal trench. The second dielectric layer is formed with a metal plate and a connection via. The connection via interconnects the metal plate and the first metal trench. The hyper via penetrates the third dielectric layer and is connected to the metal plate. The hyper via is at least 1.5 times wider than the connection via.

### BACKGROUND

The semiconductor integrated circuit (IC) industry has over the past decades experienced tremendous advancements and is still experiencing vigorous development. However, advances in IC design need to be accompanied by improvements in manufacturing in order to optimize device performance. As an example, interconnections between different layers of wires and associated dielectrics play a role in IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a sectional view illustrating an interconnection structure in accordance with a first embodiment.

FIG. 2 is a sectional view illustrating an interconnection structure in accordance with a second embodiment.

FIG. 3 shows multiple schematic diagrams each illustrating a top view of a metal plate in an interconnection structure in accordance with some embodiments.

FIG. 4 shows multiple schematic diagrams each illustrating a connection between one or more regular metal vias and a metal plate in an interconnection structure in accordance with some embodiments.

FIG. 5 is a top view illustrating a circuit layout that includes an interconnection structure in accordance with some embodiments.

FIG. 6 is a top view illustrating a circuit layout that includes an interconnection structure in accordance with some embodiments.

FIG. 7 is a top view illustrating a circuit layout that includes an interconnection structure in accordance with some embodiments.

FIG. 8 is a flow chart illustrating a method for fabricating an interconnection structure in accordance with some embodiments.

FIGS. 9 through 17 are sectional views illustrating intermediate steps of a method for fabricating an interconnection structure in accordance with some embodiments.

FIG. 18 is a sectional view illustrating an interconnection structure in accordance with some embodiments.

FIG. 19 is a sectional view illustrating an interconnection structure in accordance with some embodiments.

FIG. 20 is a flow chart illustrating a method for fabricating an interconnection structure in accordance with some embodiments.

FIGS. 21 through 26 are sectional views illustrating intermediate steps of a method for fabricating an interconnection structure in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

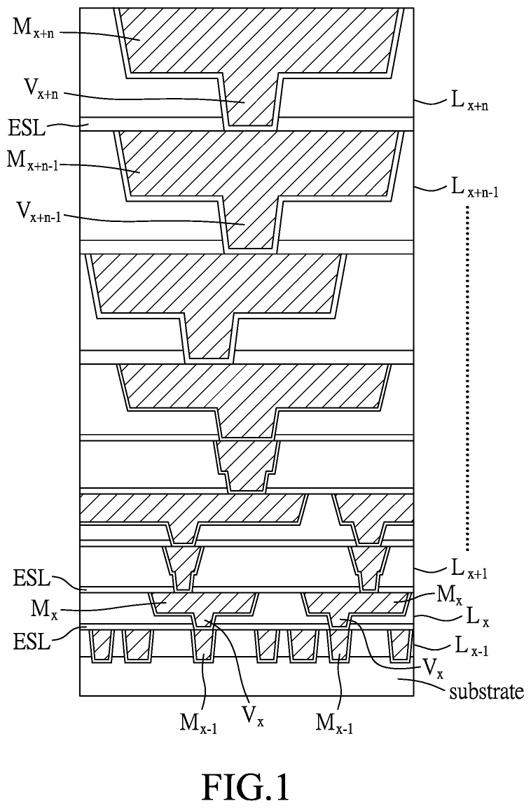

FIG. 1 illustrates a sectional view of an interconnection structure that is formed over a substrate in accordance with a first embodiment. The substrate may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The substrate may be made of a suitable semiconductor material, such as silicon or the like. In some embodiments, the substrate is a silicon substrate; and in other embodiments, the substrate is made of a compound semiconductor such as silicon carbide, gallium arsenide, indium arsenide, indium phosphide or other suitable materials. In still other embodiments, the substrate is made of an alloy semiconductor such as GaAsP, AlInAs, AlGaAs, GaInAs, GaInP, GaInAsP or other suitable materials.

In some embodiments, the substrate includes various p-type doped regions and/or n-type doped regions, such as p-type wells, n-type wells, p-type source/drain features and/or n-type source/drain features (source/drain feature(s) may refer to a source or a drain, individually or collectively depending upon the context), formed by a suitable process such as ion implantation, thermal diffusion, a combination thereof, or the like. In some embodiments, the substrate may include other functional elements such as resistors, capacitors, diodes, transistors, and/or the like. The transistors are, for example, field effect transistors (FETs), such as planar FETs and/or 3D FETs (e.g., FinFETs, GAAFETs). The substrate may include lateral isolation features (e.g., shallow trench isolation (STI)) configured to separate various functional elements formed on the substrate and/or various functional elements formed in the substrate.

In accordance with some embodiments, the substrate may be formed with a plurality of interconnection layers, and the interconnection layers may have either the same or different interconnection structures. Multiple interconnection layers Lₓ₋₁ to Lₓ₊ₙ, are formed over the substrate and stacked in the given order from bottom to top, where x is an integer greater than 1, and n is a positive integer. Each of the interconnection layers Lₓ₋₁ to Lₓ₊ₙ includes one or more metal trenches (or called metal wires) that extend in one or more lateral directions in the interconnection layer. For example, the interconnection layer Lₓ₋₁ includes multiple metal trenches Mₓ₋₁ that are connected to circuit components (e.g., transistors, diodes, etc., not shown) in the substrate, the interconnection layer Lₓ, which is separated from the immediately lower interconnection layer Lₓ₋₁ by an etch stop layer (ESL), includes multiple metal trenches Mₓ, and multiple metal vias Vₓ that connect the metal trenches Mₓ to the metal trenches Mₓ₋₁. It is noted that the term “immediately” is used to signify that there is no other interconnection layer between the aforesaid two interconnection layers (e.g., the interconnection layers Lₓ and Lₓ₋₁ herein). Through the interconnections among metal trenches and metal vias in the interconnection layers Lₓ to Lₓ₊ₙ, a metal trench Mₓ+n that is formed in the interconnection layer Lₓ₊ₙ is electrically connected to one of the metal trenches Mₓ₋₁ that is formed in the interconnection layer Lₓ₋₁ as well as the circuit component(s) in the substrate the metal trench Mₓ₋₁ is electrically connected to.

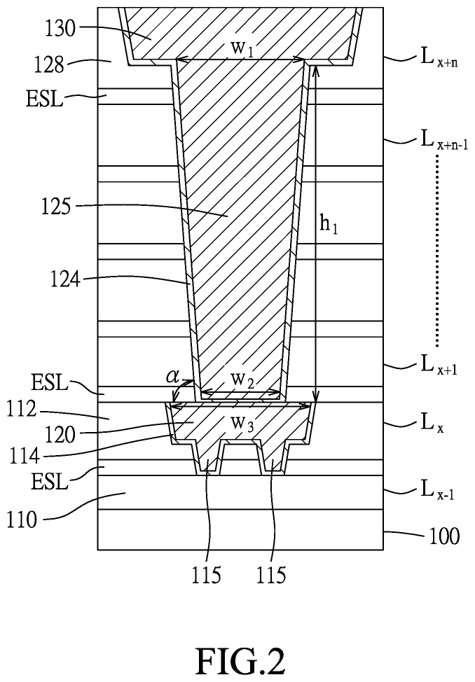

FIG. 2 illustrates a sectional view of an interconnection structure that is formed over a substrate 100 in accordance with a second embodiment, where the substrate 100 is similar to the substrate of the first embodiment, so details thereof are omitted herein for the sake of brevity. In the illustrative embodiment, multiple interconnection layers Lₓ₋₁ to Lₓ₊ₙ are formed over the substrate 100 and stacked in the given order from bottom to top, where x is an integer greater than 1, and n is a positive integer. Each of the interconnection layers Lₓ₋₁ to Lₓ₊ₙ includes a dielectric layer, and one or more metal trenches (not every interconnection layer is shown to include one or more metal trenches in FIG. 2) that are formed in the dielectric layer and that extend in one or more lateral directions that are parallel to a surface of the substrate 100 (e.g., a top surface of the substrate 100 from the perspective of FIG. 2). The dielectric layer may contain elements of, for example, Si, O, C, N, H, other suitable elements, or any combination thereof. In accordance with some embodiments, the dielectric layer may include, for example, silicon oxide, silicon nitride, silicon carbide, low-k materials, other suitable materials, or any combination thereof. In accordance with some embodiments, the dielectric layer may have a thickness in a range from about 200 angstroms to about 2000 angstroms, but this disclosure is not limited in this respect. Interposed between adjacent two interconnection layers is an etch stop layer (ESL), which may have either a single-layer structure or a multi-layer structure, and contain elements of, for example, Si, O, C, N, H, Al, other suitable elements, or any combination thereof. In accordance with some embodiments, the etch stop layer may include, for example, silicon oxide, silicon nitride, silicon carbide, aluminum oxide, aluminum nitride, aluminum carbide, other suitable materials, or any combination thereof. In accordance with some embodiments, the etch stop layer may have a thickness in a range from about 5 angstroms to about 200 angstroms, but this disclosure is not limited in this respect.

In the illustrative embodiment, the interconnection layer Lₓ₋₁ includes a metal trench 110, the interconnection layer Lₓ₊ₙ includes a metal trench 130, and the metal trench 130 is electrically connected to the metal trench 110 through a hyper metal via 125, a metal plate 120 and regular metal vias 115.

In detail, the metal trench 110 of the interconnection layer Lₓ₋₁ is formed in a dielectric layer (not shown in FIG. 2) of the interconnection layer Lₓ₋₁, and extends in a lateral direction (a left-right direction from the perspective of FIG. 2). An etch stop layer (ESL) is formed over the interconnection layer Lₓ₋₁. The interconnection layer Lₓ is disposed immediately above the interconnection layer Lₓ₋₁ (as mentioned above, the term “immediately” is used to signify that no other interconnection layer is disposed between the aforesaid two interconnection layers, which are the interconnection layers Lₓ and Lₓ₋₁ herein), and includes a dielectric layer 112, the metal plate 120, the regular metal vias 115, and a liner (or barrier) 114. The metal plate 120 and the regular metal vias 115 are formed in the dielectric layer 112, and each regular metal via 115 extends from the metal plate 120 to the metal trench 110, and penetrates the etch stop layer (ESL) that is disposed between the interconnection layers Lₓ and Lₓ₋₁, so as to electrically connect the metal plate 120 to the metal trench 110. In accordance with some embodiments, a single regular metal via 115 or more than two regular metal vias 115 may be formed to electrically interconnect the metal plate 120 and the metal trench 110, and this disclosure is not limited to the number of the regular metal vias 115. In the illustrative embodiment, the regular metal vias 115 are similar to the metal vias in FIG. 1, each of which extends only between conductive components (e.g., a metal trench, a metal plate, etc.) in two adjacent interconnection layers (namely, two interconnection layers with no other interconnection layers interposed therebetween, e.g., the interconnection layers Lₓ and Lₓ₋₁ herein), and does not penetrate an entire single interconnection layer from top to bottom. The liner 114 is disposed between the metal plate 120 and the dielectric layer 112 and between the regular metal vias 115 and the dielectric layer 112 for preventing diffusion of metal elements of the metal plate 120 and the regular metal vias 115 into the dielectric layer 112. The metal trench 130 of the interconnection layer Lₓ₊ₙ is formed in a dielectric layer 128 of the interconnection layer Lₓ₊ₙ, and extends in another lateral direction (an inward-outward direction from the perspective of FIG. 2 (into and out of the page)). The hyper metal via 125 extends in a straight line (namely, without bending or curving) from the metal trench 130 to the metal plate 120, and penetrates the dielectric layers of the interconnection layers Lₓ+1 to Lₓ₊ₙ₋₁ and etch stop layers among the interconnection layers Lₓ₊₁ to Lₓ₊ₙ₋₁. A liner 124 is disposed between the metal trench 130 and the dielectric layer 128, and between the hyper metal via 125 and the dielectric layers of the interconnection layers Lₓ₊₁ to Lₓ₊ₙ for preventing diffusion of metal elements of the metal trench 130 and the hyper metal via 125 into the dielectric layers. In accordance with some embodiments, each of the metal trenches 110 and 130, the regular metal vias 115, the metal plate 120 and the hyper metal via 125 may include, for example, Cu, Ru, W, Ti, Al, Co, Mo, Ir, Rh, Ta, other suitable materials, or any combination thereof. The metal trenches 110 and 130, the regular metal vias 115, the metal plate 120 and the hyper metal via 125 may be made of the same or different materials. In accordance with some embodiments, the liners 114 and 124 may include, for example, Ru, W, Ti, Al, Co, Mo, Ir, Rh, Ta, any nitride of these metals, other suitable materials, or any combination thereof. In accordance with some embodiments, the liners 114 and 124 may be omitted depending on the bulk metal used in the metal trenches 110 and 130, the regular metal vias 115, the metal plate 120 and the hyper metal via 125, and this disclosure is not limited in this respect.

In accordance with some embodiments, the hyper metal via 125 is made to be tall and wide (at least 1.5 times wider than the regular metal via 115, and in some embodiments, about 2 to 15 times wider than the regular metal via 115 for better electrical resistance), thereby penetrating one or more dielectric layers while having a low electrical resistance, and thus achieving a better resistance-capacitance delay in comparison to the first embodiment. In some examples, the hyper metal via 125 has a height h₁ in a range from about 200 nm to about 900 nm, a top width w₁ (i.e., a width of a top of the hyper metal via 125) in a range from about 40 nm to about 150 nm, a bottom width w₂ (i.e., a width of a bottom of the hyper metal via 125) in a range from about 10 nm to about 60 nm, an aspect ratio (i.e., a ratio of the height h₁ to the top width w₁) in a range from about 3 to about 6, and/or an angle α formed by a side surface of the hyper metal via 125 and a top surface of the metal plate 120 in a range from about 75 degrees to about 90 degrees. In addition to achieving a low electrical resistance, the design of the great width of the hyper metal via 125 may also reduce difficulties in forming and filling a deep via hole to make the hyper metal via 125. Meeting one or more of the aforesaid conditions may make the hyper metal via 125 have an acceptable electrical resistance as well as a reduced difficulty in terms of fabrication. The metal trench 130 and the hyper metal via 125 may be formed using either a single damascene process or a dual damascene process. In accordance with some embodiments, the metal trench 130 may have a width in a range from about 10 nm to about 200 nm. In a case where the metal trench 130 and the hyper metal via 125 are formed using a dual damascene process, the metal trench 130 may be wider than the top width w₁ of the hyper metal via 125.

In accordance with some embodiments, a line spacing (i.e., a distance between adjacent two metal trenches) for the interconnection layer Lₓ₋₁ may be small, and if the hyper metal via 125 directly lands on the metal trench 110 of the interconnection layer Lₓ₋₁, the bottom of the hyper metal via 125 may undesirably contact another metal trench (not shown in FIG. 2) that is adjacent to the metal trench 110. Therefore, the metal plate 120 in the interconnection layer Lₓ is made to serve as an intermediary for electrically connecting the hyper metal via 125 to the metal trench 110 through the smaller regular metal vias 115. The metal plate 120 is wider than the bottom width w₂ of the hyper metal via 125, so the hyper metal via 125 can completely stand on the metal plate 120. In accordance with some embodiments, a top surface of the metal plate 120 (i.e., the surface the hyper metal via 125 stands on) has a width w₃ in a range from about 40 nm to about 150 nm.

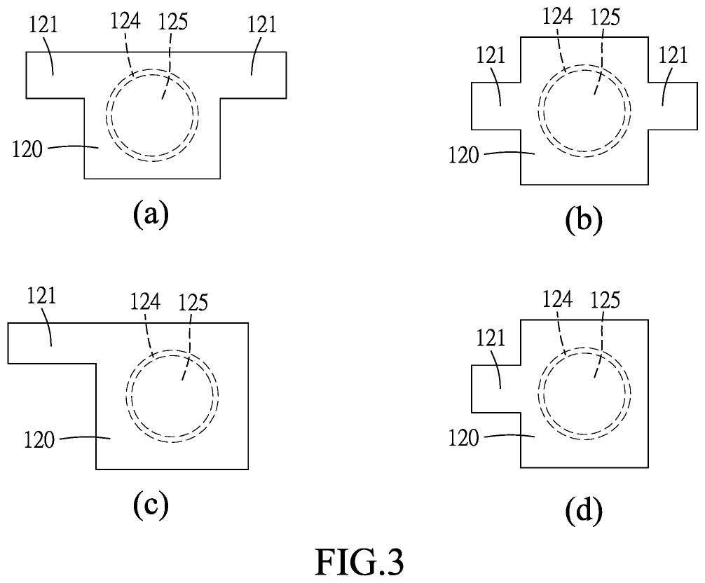

Further referring to FIG. 3, the metal plate 120 is exemplified as having a rectangular top view. Broken lines in FIG. 3 depict contours of the bottom of the hyper metal via 125 and the surrounding liner 124. It can be seen that the hyper metal via 125 is completely located on the metal plate 120, which has a top surface larger than the bottom of the hyper metal via 125. The metal plate 120 has a first length in a first lateral direction (e.g., an up-down direction from the perspective of FIG. 3), and a second length in a second lateral direction (e.g., a left-right direction from the perspective of FIG. 3) that is perpendicular to the first lateral direction. Each of the first length and the second length can be seen to be the aforesaid width w₃ of the metal plate 120, which is in a range from about 40 nm to about 150 nm. Parts (a) to (d) of FIG. 3 illustrate different ways the metal plate 120 is connected to one or more metal trenches 121 that are disposed in the same interconnection layer. In part (a) of FIG. 3, the metal plate 120 is connected to a metal trench 121 at one side of an upper portion thereof, and is connected to another metal trench 121 at another side of the upper portion thereof. In part (b) of FIG. 3, the metal plate 120 is connected to a metal trench 121 at one side of a central portion thereof, and is connected to another metal trench 121 at another side of the central portion thereof. In part (c) of FIG. 3, the metal plate 120 is connected to only one metal trench 121 at one side of the upper portion thereof. In part (d) of FIG. 3, the metal plate 120 is connected to only one metal trench 121, and said only one metal trench 121 is connected at one side of the central portion of the metal plate 120. In accordance with some embodiments, the metal plate 120 may be connected to more metal trenches at different sides and/or different portions thereof, and this disclosure is not limited in this respect. In accordance with some embodiments, the metal plate 120 may be a standalone feature with no metal trenches in the same interconnection layer connected thereto, in which case the metal plate 120 is formed for the purpose of supporting the hyper metal via 125.

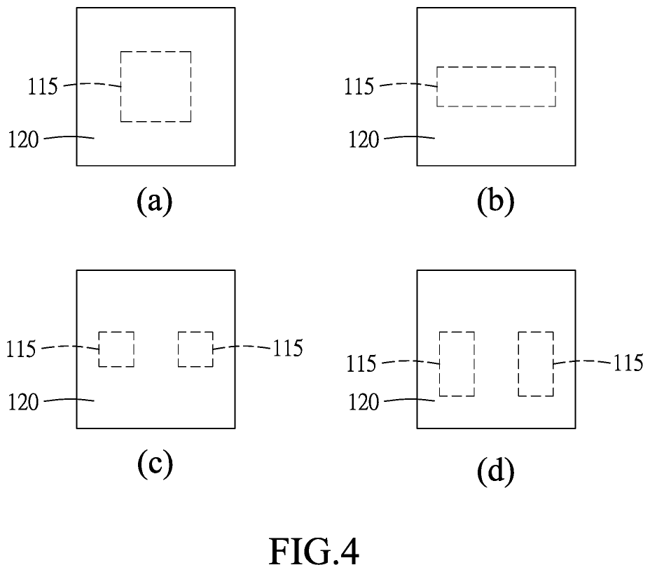

In FIG. 4, the metal plate 120 is also exemplified as having a rectangular top view, and broken lines are used to illustrate contour(s) of the top(s) of the regular metal via(s) 115 (namely, the junction(s) between the regular metal via(s) 115 and the metal plate 120). In part (a) of FIG. 4, only one regular metal via 115 is connected to the metal plate 120, and the regular metal via 115 has a square top view. In part (b) of FIG. 4, only one regular metal via 115 is connected to the metal plate 120, and the regular metal via 115 has a rectangular top view. In part (c) of FIG. 4, multiple regular metal vias 115 are connected to the metal plate 120, and each regular metal via 115 has a square top view. In part (d) of FIG. 4, multiple regular metal vias 115 are connected to the metal plate 120, and each regular metal via 115 has a rectangular top view). It is noted that the regular metal via or vias 115 are not limited to be located at the center of the metal plate 120 or have any specific arrangement, and can be formed to have a top view of any shape. In accordance with some embodiments, each side of each regular metal via 115 may have a length in a range from about 10 nm to about 100 nm, but this disclosure is not limited in this respect.

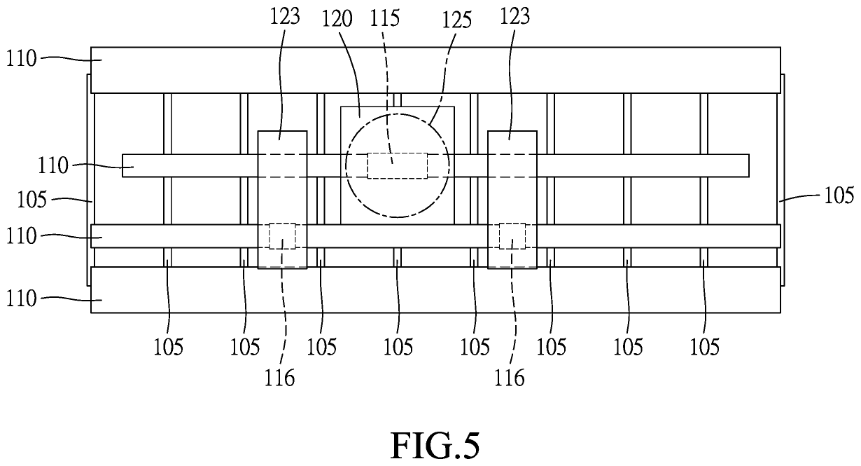

FIG. 5 illustrates a first exemplary circuit layout that includes the interconnection structure in accordance with some embodiments. Metal lines 105 are, for example, gate electrodes of transistors that are formed in the substrate (e.g., the substrate 100 in FIG. 2). The metal lines 105 are parallel to each other, and extend in a first lateral direction (e.g., an up-down direction from the perspective of FIG. 5) that is parallel to a top surface of the substrate. Metal trenches 110 are formed in a first interconnection layer (e.g., the interconnection layer Mₓ₋₁ in FIG. 2) that is disposed over the substrate, extend in a left-right direction from the perspective of FIG. 5, and are parallel to each other. The metal trenches 110 may be formed to have different widths in the up-down direction from the perspective of FIG. 5. For example, some of the metal trenches 110 (e.g., the top and the bottom metal trenches 110 in FIG. 5) that are made for power transmission purposes may have greater widths than those of other metal trenches 110 that are made for signal transmission purposes. A metal plate 120, a regular metal via 115 (plotted using broken lines within the metal plate 120), multiple metal trenches 123, and multiple regular metal vias 116 (plotted using broken lines within the metal trenches 123) are formed in a second interconnection layer (e.g., the interconnection layer Mₓ in FIG. 2) that is immediately above the first interconnection layer. The metal trenches 123 extend in the first lateral direction, and are electrically connected to one of the metal trenches 110 in the first interconnection layer through the regular metal vias 116. The metal plate 120 is spaced apart from the metal trenches 123 in a second lateral direction (e.g., the left-right direction from the perspective of FIG. 5) that is parallel to the top surface of the substrate, and has an overlapping portion that overlaps one of the metal trenches 110 (referring to as “target metal trench” hereinafter) in a vertical direction (e.g., an inward-outward direction from the perspective of FIG. 5 (into and out of the page)) that is perpendicular to the top surface of the substrate. It is noted that there is no specific restrictions on the distance between the metal plate 120 and an adjacent metal trench 123, as long as a general minimum spacing rule is conformed with. The regular metal via 115 extends from the overlapping portion of the metal plate 120 to the target metal trench 110. In FIG. 5, a chain line is used to plot a contour of a bottom of a hyper metal via 125 that is wider than the target metal trench 110 and that stands on the metal plate 120 and overlaps the regular metal via 115 in the vertical direction. As a result, the hyper metal via 125 is electrically connected to the target metal trench 110 through the metal plate 120 and the regular metal via 115.

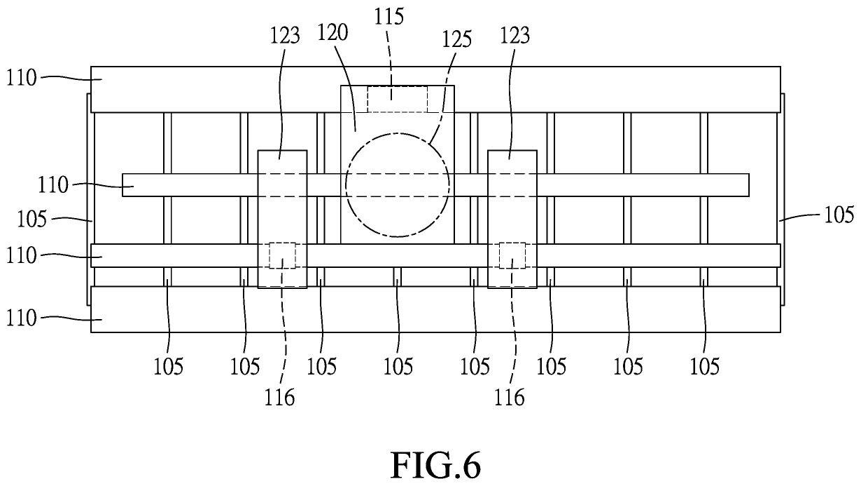

FIG. 6 illustrates a second exemplary circuit layout that includes an interconnection structure in accordance with some embodiments. The second exemplary circuit layout is similar to the first exemplary circuit layout, and differs from the first exemplary circuit layout in that the target metal trench 110 is the uppermost metal trench 110 in FIG. 6. In this case, the target metal trench 110 may be a power line that is located at an edge of a circuit cell, and thus is close to an adjacent circuit cell (not shown) that is located at an upper side of the circuit cell that includes the target metal trench 110 (“upper” from the perspective of FIG. 6). If the hyper metal via 125 of a large size overlaps the target metal trench 110 in the inward-outward direction, the hyper metal via 125 may occupy a part of the adjacent circuit cell, increasing complexity in circuit design. In order to avoid such a condition, the metal plate 120 may be formed to have a center deviated from the target metal trench 110, and to have an edge portion that overlaps the target metal trench 110 (namely, the edge portion serves as the overlapping portion), in which case the regular metal via 115 extends from the edge portion of the metal plate 120 to the target metal trench 110, and the hyper metal via 125 stands on the remaining portion of the metal plate 120 that does not overlap the target metal trench 110. As illustrated in FIG. 6, by virtue of the metal plate 120, the hyper metal via 125 is not necessarily located directly over the target metal trench 110, and can be located at another location as desired, such as a location overlapping another metal trench 110 that is adjacent to the target metal trench 110.

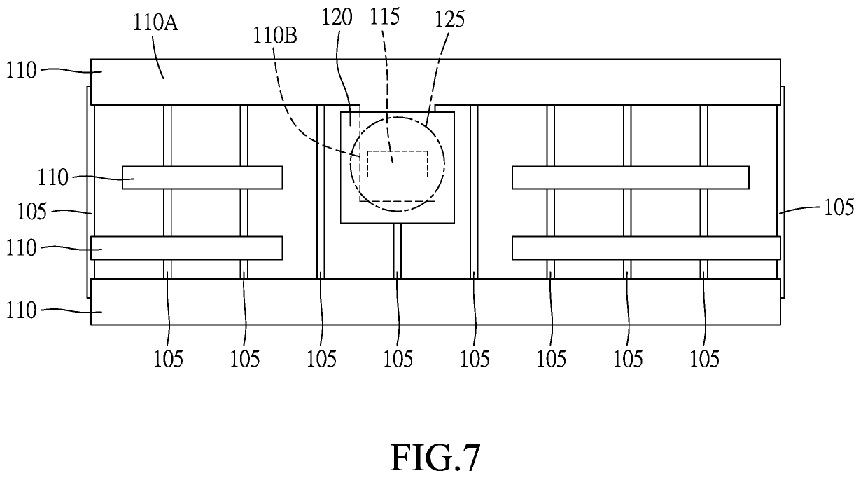

FIG. 7 illustrates a third exemplary circuit layout that includes an interconnection structure in accordance with some embodiments. The third exemplary circuit layout is similar to the second exemplary circuit layout, and differs from the second exemplary circuit layout in that the target metal trench 110 has a line portion 110A that extends in a straight line in the second lateral direction, and a protruding portion (also called a jog) 110B that extends from the line portion 110A laterally (e.g., in the first lateral direction). The metal plate 120 has a portion (referred to as “overlapping portion” hereinafter) that overlaps the protruding portion 110B of the target metal trench 110, and the regular metal via 115 extends from the overlapping portion of the metal plate 120 to the protruding portion 110B of the target metal trench 110. By virtue of the protruding portion 110B, the hyper metal via 125 is not necessarily located directly over the line portion 110A of the target metal trench 110, which may be located at an edge of a circuit cell and close to an adjacent circuit cell (not shown), thereby preventing the hyper metal via 125 from partly occupying the adjacent circuit cell.

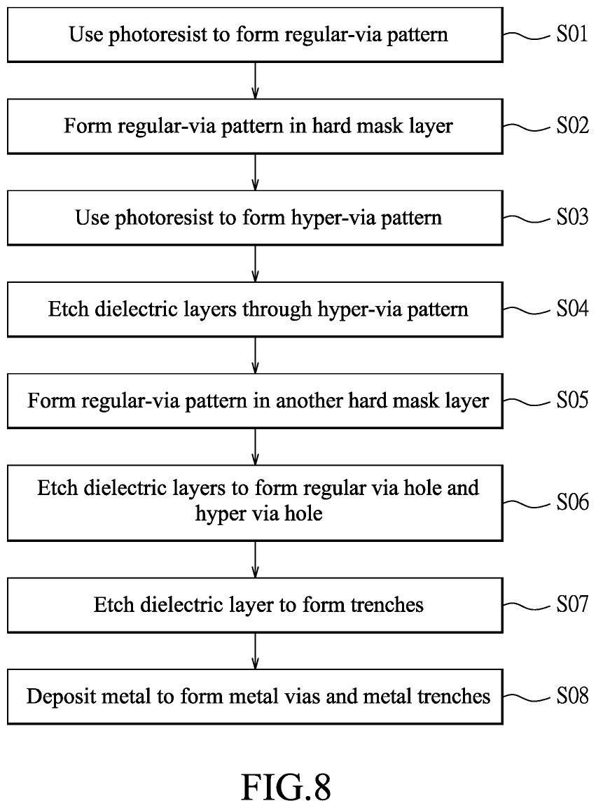

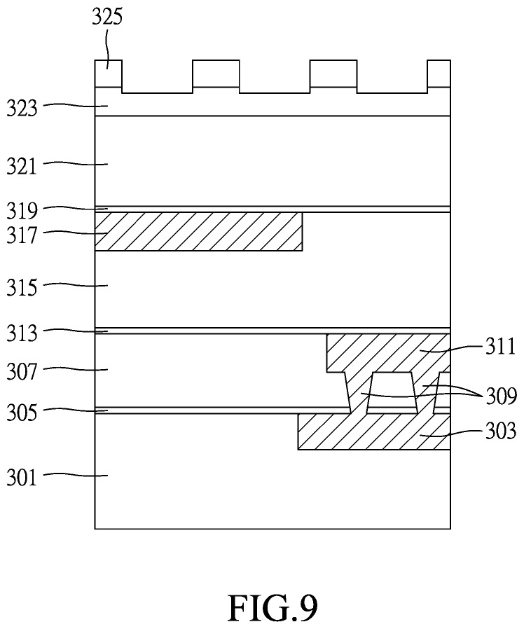

FIG. 8 is a flow chart that cooperates with FIGS. 9 through 17 to illustrate steps of using a dual damascene process to form an interconnection structure that includes a hyper metal via according to some embodiments.

In FIG. 9, a first interconnection layer is shown to include a first dielectric layer 301, and a metal trench 303 that is formed in the first dielectric layer 301; a second interconnection layer is disposed immediately over the first interconnection layer with an etch stop layer 305 interposed between the first interconnection layer and the second interconnection layer, and includes a second dielectric layer 307, and multiple regular metal vias 309 and a metal plate 311 that are formed in the second dielectric layer 307; and an intermediate interconnection layer is disposed over the second interconnection layer with an etch stop layer 313 interposed between the second interconnection layer and the intermediate interconnection layer, and includes a third dielectric layer 315, and a metal trench 317 that is formed in the third dielectric layer 315. The regular metal vias 309 extend between the metal plate 311 and the metal trench 303 in a vertical direction from the perspective of FIG. 9, and penetrate the etch stop layer 305, thereby electrically interconnecting the metal plate 311 and the metal trench 303. A fourth dielectric layer 321 is disposed over the intermediate interconnection layer with an etch stop layer 319 interposed between the intermediate connection layer and the fourth dielectric layer 321. In the illustrative embodiment, only one intermediate interconnection layer is formed between the fourth dielectric layer 321 and the second dielectric layer 307; in other embodiments, multiple intermediate interconnection layers may be formed between the fourth dielectric layer 321 and the second dielectric layer 307, and this disclosure is not limited in this respect. A metal hard mask layer 325 is disposed over the fourth dielectric layer 321 with a capping layer 323 interposed between the fourth dielectric layer 321 and the metal hard mask layer 325, and the metal hard mask layer 325 is etched to form a metal-trench pattern therein. In the illustrative embodiment, the metal hard mask layer 325 is etched into multiple segments, thereby forming, among the segments, a plurality of trenches that cooperatively form the metal-trench pattern. In accordance with some embodiments, the metal hard mask layer 325 includes metal elements, such as W, Ti, other suitable metal elements, or any combination thereof, for enhancing resistance against etchants that are used for etching dielectrics (e.g., material(s) that are used to form the first, second, third and/or fourth dielectric layer), so that the metal hard mask layer 325 would remain after the etching of the dielectric(s). In accordance with some embodiments, the capping layer 323 may include, for example, Si, O, N, C, other suitable elements, or any combination thereof, for enhancing adhesion between the metal hard mask layer 325 and the fourth dielectric layer 321, so as to avoid peeling of the metal hard mask layer 325 from the fourth dielectric layer 321. In accordance with some embodiments, the capping layer 323 may include, for example, Si-based oxide, Si-based nitride, Si-based carbide, other suitable materials, or any combination thereof.

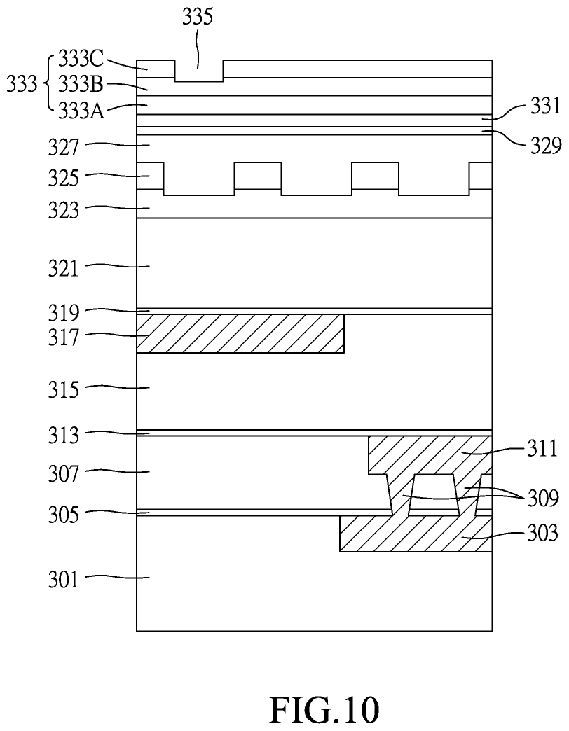

Referring to FIGS. 8 and 10, a fifth dielectric layer 327, a first hard mask layer 329, a second hard mask layer 331 and a tri-layer photoresist 333 are formed over the metal hard mask layer 325 and the capping layer 323 in the given order from bottom to top. The tri-layer photoresist 333 includes a bottom layer 333A (e.g., a lift-off resist layer), a middle layer 333B (e.g., a back anti-reflection coating layer), and a top layer 333C (e.g., a photosensitive layer). The tri-layer photoresist 333 is formed with a regular-via pattern 335 (step S01) that will be transferred to the second hard mask layer 331 in a later step, where the regular-via pattern 335 corresponds to regular metal vias to be formed in the fourth dielectric layer 321. In the illustrative embodiment, a portion of the regular-via pattern 335 overlaps the metal trench 317 in the vertical direction, and corresponds to a regular metal via that is to be formed later and connected to the metal trench 317. In accordance with some embodiments, the fifth dielectric layer 327 may include, for example, a polymer, an oxide material, a nitride material, a carbide material, other suitable materials, or any combination thereof. In accordance with some embodiments, each of the first hard mask layer 329 and the second hard mask layer 331 may include, for example, Si-based or metal-based (e.g., W, Ti, Ta, or other suitable metal elements) nitride, Si-based or metal-based carbide, other suitable materials, or any combination thereof. In accordance with some embodiments, the first hard mask layer 329 and the second hard mask layer 331 include different materials, so as to achieve an etching selectivity therebetween, preventing the first hard mask layer 329 from being removed during the etching of the second hard mask layer 331.

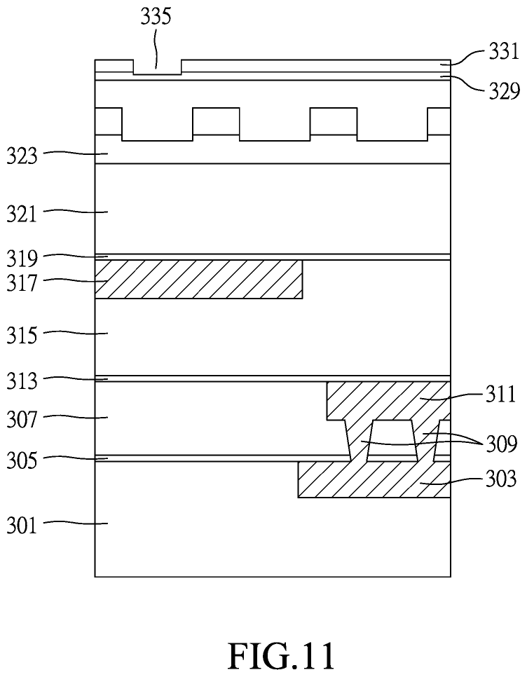

Referring to FIGS. 8 and 11, the second hard mask layer 331 is etched with the tri-layer photoresist 333 (see FIG. 10) serving as an etching mask, so as to form the regular-via pattern 335 in the second hard mask layer 331 (step S02). The etching of the second hard mask layer 331 may be performed using, for example, dry etching, wet etching, other suitable etching techniques, or any combination thereof. The first hard mask layer 329 may also be slightly etched at a top portion thereof during the etching of the second hard mask layer 331, so as to ensure that the second hard mask layer 331 is completely removed at positions where the regular-via pattern 335 is formed. Since the first hard mask layer 329 and the second hard mask layer 331 are made to have the etching selectivity therebetween, it is controllable to make the first hard mask layer 329 remain after etching the second hard mask layer 331.

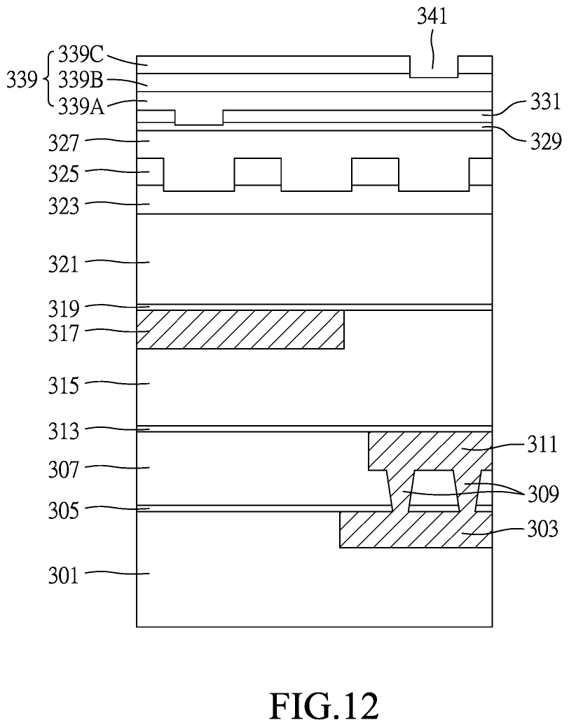

Referring to FIGS. 8 and 12, a tri-layer photoresist 339 is formed over the second hard mask layer 331 and the first hard mask layer 329. Similar to the tri-layer photoresist 333 (see FIG. 10), the tri-layer photoresist 339 includes a bottom layer 339A (e.g., a lift-off resist layer), a middle layer 339B (e.g., a back anti-reflection coating layer), and a top layer 339C (e.g., a photosensitive layer). The tri-layer photoresist 339 is formed with a hyper-via pattern 341 (step S03) that will be transferred to the first hard mask layer 329 in a later step, where the hyper-via pattern 341 corresponds to one or more hyper metal vias to be formed to penetrate the fourth dielectric layer 321 and the intermediate interconnection layer and land on the metal plate 311. In the illustrative embodiment, a portion of the hyper-via pattern 341 overlaps the metal plate 311 in the vertical direction, and corresponds to one or more hyper metal vias to be connected to the metal plate 311.

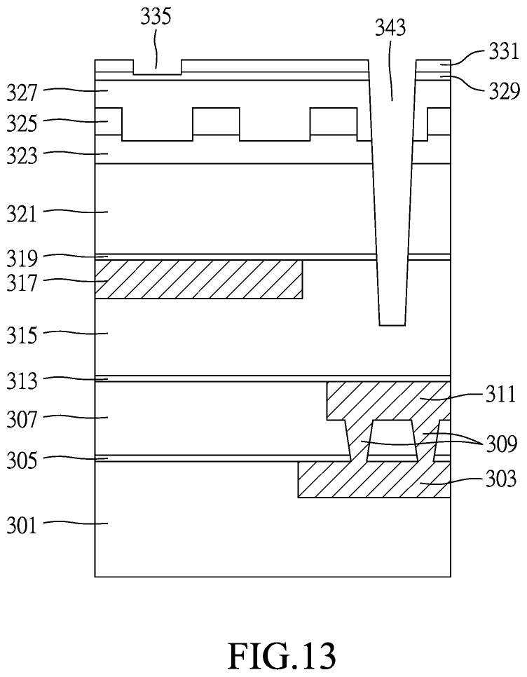

Referring to FIGS. 8 and 13, the dielectric layers between the first hard mask layer 329 and the metal plate 311 are etched (step S04) through the hyper-via pattern 341 that is formed in the tri-layer photoresist 339 (see FIG. 12). In detail, the second hard mask layer 331, the first hard mask layer 329, the fifth dielectric layer 327, the capping layer 323, the fourth dielectric layer 321, the etch stop layer 319 and the third dielectric layer 315 are etched with the tri-layer photoresist 339 serving as an etching mask. In accordance with some embodiments, the etching may be performed using, for example, anisotropic etching, which is suitable for forming a deep hyper via hole 343 with a high aspect ratio and a good profile, but this disclosure is not limited in this respect, and other suitable etching techniques may be applied in other embodiments. In the illustrative embodiment, the etching of the hyper via hole 343 stops at midway through the third dielectric layer 315, and does not reach the metal plate 311 in this step. The remaining thickness of the third dielectric layer 315 will be etched during the subsequent etching with respect to the regular-via pattern 335, so as to reduce time required for the etching process.

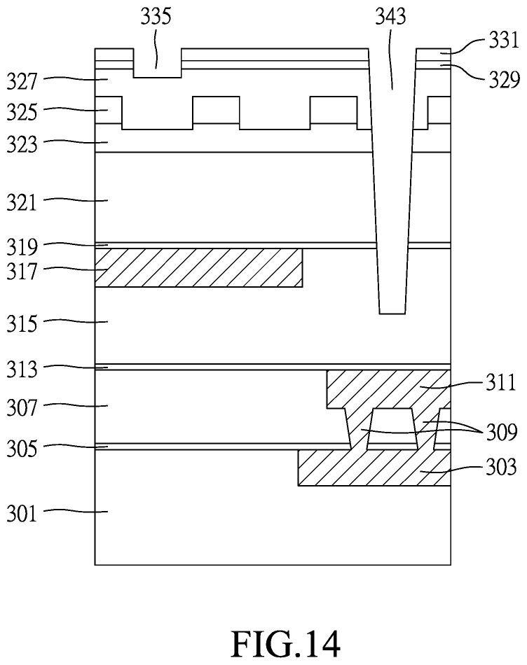

Referring to FIGS. 8 and 14, the first hard mask layer 329 is etched with the second hard mask layer 331 that has the regular-via pattern 335 formed therein serving as an etching mask, so as to transfer the regular-via pattern 335 into the first hard mask layer 329 (step S05). The etching of the first hard mask layer 329 may be performed using, for example, dry etching, wet etching, other suitable etching techniques, or any combination thereof.

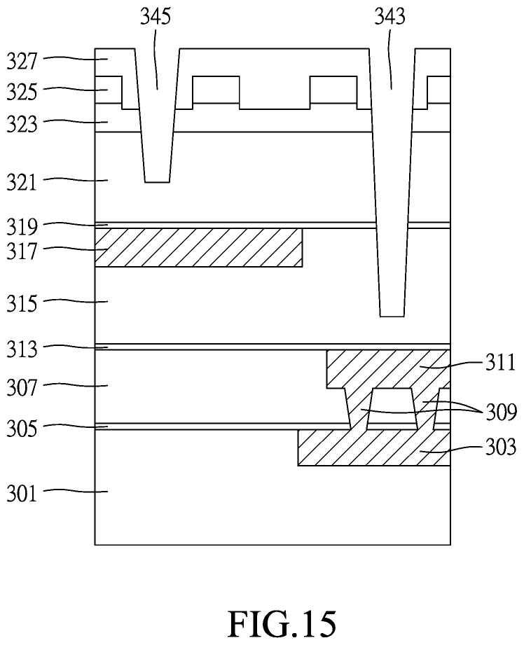

Referring to FIGS. 8 and 15, a process of etching dielectric layers is performed (step S06), so that the fifth dielectric layer 327 and the fourth dielectric layer 321 are etched through the regular-via pattern 335 (see FIG. 14) that is formed in the first hard mask layer 329 (see FIG. 14), and the third dielectric layer 315 is further etched through the hyper-via pattern (i.e., the hyper via hole 343). As a result, a regular via hole 345 is formed in the fourth dielectric layer 321, and the hyper via hole 343 is etched to be deeper in the interconnection structure. The etching process may be performed using, for example, anisotropic etching, other suitable techniques, or any combination thereof. In the illustrative embodiment, the etching stops when a depth of the regular via hole 345 reaches a middle of the fourth dielectric layer 321 and when a depth of the hyper via hole 343 reaches a lower portion of the third dielectric layer 315. The remaining thickness of the fourth dielectric layer 321 that corresponds in position to the regular via hole 345 and the remaining thickness of the third dielectric layer 315 that corresponds in position to the hyper via hole 343 will be etched during a subsequent trench-forming process, so as to reduce time required for the etching process in this step. During the process of etching dielectric layers to deepen the regular via hole 345 and the hyper via hole 343, the second hard mask 331 (see FIG. 14) and the first hard mask 329 (see FIG. 14) may be removed.

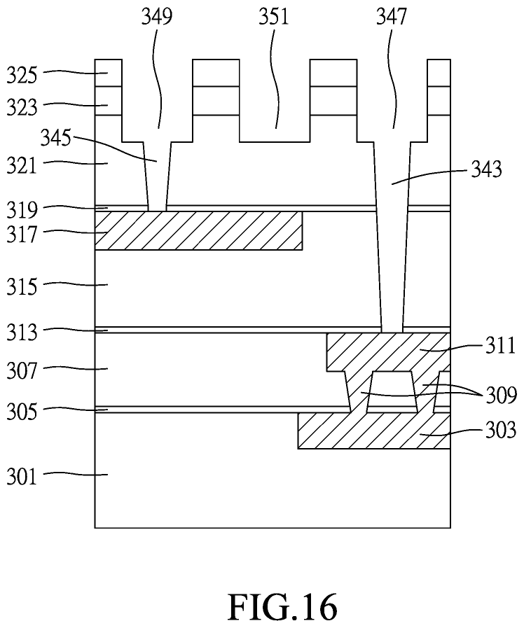

Referring to FIGS. 8 and 16, a trench-forming process is performed (step S07) to remove the fifth dielectric layer 327 (see FIG. 15) and to etch the capping layer 323 and the fourth dielectric layer 321 with the metal hard mask layer 325 that has the metal-trench pattern formed therein serving as an etching mask, so as to form trenches 347, 349 and 351 in the fourth dielectric layer 321. During the formation of the trenches 347, 349 and 351, the regular via hole 345 and the hyper via hole 343 may be further deepened together to respectively reach the etch stop layers 319 and 313, which will be later etched to reveal the metal trench 317 and the metal plate 311. In accordance with some embodiments, the removal of the fifth dielectric layer 327, and the etching of the capping layer 323 and the fourth dielectric layer 321 may be performed using, for example, anisotropic etching, other suitable techniques, or any combination thereof, but this disclosure is not limited in this respect.

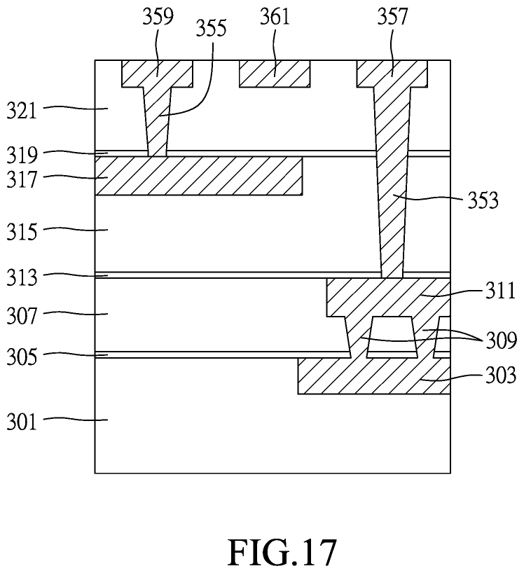

Further referring to FIG. 17, a metal layer is deposited to fill up the hyper via hole 343, the regular via hole 345 and the trenches 347, 349 and 351, followed by a chemical-mechanical planarization (CMP) process to remove the metal hard mask layer 325, the capping layer 323 and excessive portions of the metal layer, thereby forming a hyper metal via 353 in the hyper via hole 343, a regular metal via 355 in the regular via hole 345, and metal trenches 357, 359 and 361 respectively in the trenches 347, 349 and 351 (step S08). The hyper metal via 353 extends between the metal trench 357 and the metal plate 311, and penetrates the third dielectric layer 315 of the intermediate interconnection layer from top to bottom. Therefore, the metal trench 357 is electrically connected to the metal trench 303 through the hyper metal via 353, the metal plate 311 and the regular metal vias 309. The regular metal via 355 extends in the fourth dielectric layer 321 between the metal trench 359 and the metal trench 317. In accordance with some embodiments, the deposition of the metal layer may include, for example, atomic layer deposition (ALD) to form a liner/barrier, chemical vapor deposition (CVD) to form a metal seed layer, and electrochemical plating (ECP) to grow the metal on the metal seed layer, but this disclosure is not limited in this respect, and the metal layer may be formed using other suitable deposition techniques and/or other suitable combinations of various deposition techniques in other embodiments.

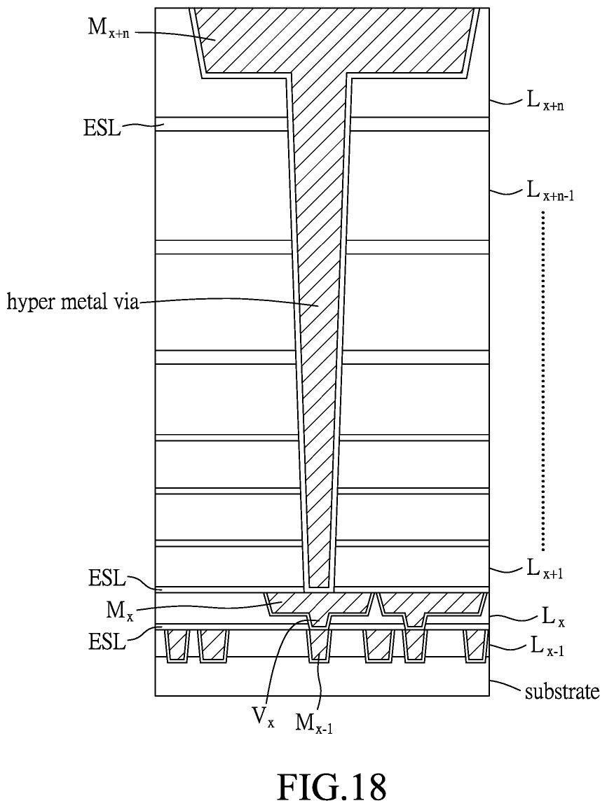

FIG. 18 illustrates an interconnection structure that includes a hyper metal via that directly extends from a metal trench Mₓ₊ₙ in an interconnection layer Lₓ₊ₙ to a metal plate Mₓ in an interconnection layer Lₓ, and that penetrates interconnection layers Lₓ₊₁ to Lₓ₊ₙ₋₁ in accordance with some embodiments. The metal plate Mₓ is electrically connected to a metal trench Mₓ₋₁ that is disposed in an interconnection layer Lₓ₋₁ through a regular metal via Vₓ. In comparison to the interconnection structure in FIG. 1, the hyper metal via in FIG. 18 provides a shorter conductive path between the metal trench Mₓ₊ₙ and the metal trench Mₓ₋₁, and fewer wide metal portions (e.g., the metal trenches in the interconnection layers Lₓ₊₁ to Lₓ₊ₙ₋₁ in FIG. 1) on the conductive path, so as to achieve a better resistance-capacitance delay.

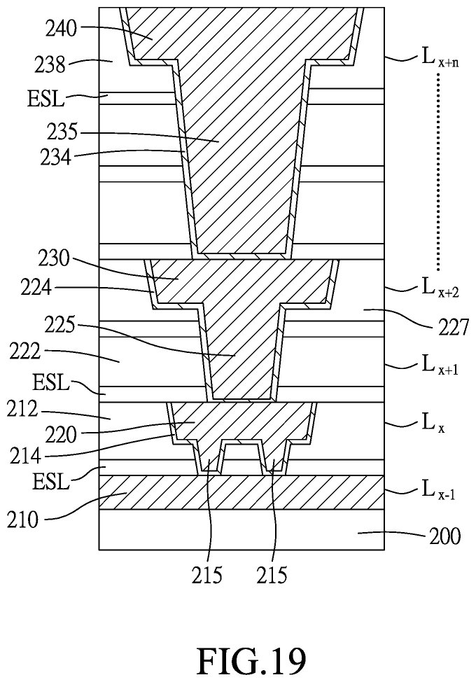

FIG. 19 illustrates an interconnection structure that includes multiple hyper metal vias stacked together in accordance with some embodiments. In the illustrative embodiment, multiple interconnection layers Lₓ₋₁ to Lₓ₊ₙ are formed over a substrate 200 in the given order from bottom to top. The interconnection layer Lₓ₋₁ includes a metal trench 210 formed therein. The interconnection layer Lₓ includes a dielectric layer 212, and a liner 214, multiple regular metal vias 215 and a first metal plate 220 formed in the dielectric layer 212, where the regular metal vias 215 extend between the first metal plate 220 and the metal trench 210, and the liner 214 is disposed between the first metal plate 220 and the dielectric layer 212 and between the regular metal vias 215 and the dielectric layer 212. The interconnection layer Lₓ₊₂ includes a dielectric layer 227, and a second metal plate 230 formed in the dielectric layer 227. A first hyper metal via 225 extends between the second metal plate 230 and the first metal plate 220, and penetrates a dielectric layer 222 of the interconnection layer Lₓ₊₁ from top to bottom. A liner 224 is disposed between the second metal plate 230 and the dielectric layer 227, between the first hyper metal via 225 and the dielectric layer 227, and between the first hyper metal via 225 and the dielectric layer 222. The interconnection layer Lₓ₊ₙ includes a dielectric layer 238, and a third metal plate 240 formed in the dielectric layer 238. A second hyper metal via 235 extends between the third metal plate 240 and the second metal plate 230, and penetrates dielectric layers between the interconnection layers Lₓ₊₂ and Lₓ₊ₙ. In other words, the second hyper metal via 235 is connected to the second metal plate 230, is stacked over and connected to the first hyper metal via 225 through the second metal plate 230, and penetrates one or more dielectric layers over the second metal plate 230. It is noted that each of the first metal plate 220, the second metal plate 230 and the third metal plate 240 may either be a standalone feature without connecting to any metal trench in the same interconnection layer, or be connected to one or more metal trenches in the same interconnection layer, and this disclosure is not limited in this respect. In accordance with some embodiments, one or more hyper metal vias may be further stacked over the second hyper metal via 235 through one or more additional metal plates (e.g., the third metal plate 240), and this disclosure is not limited to the number of hyper metal vias that are stacked together.

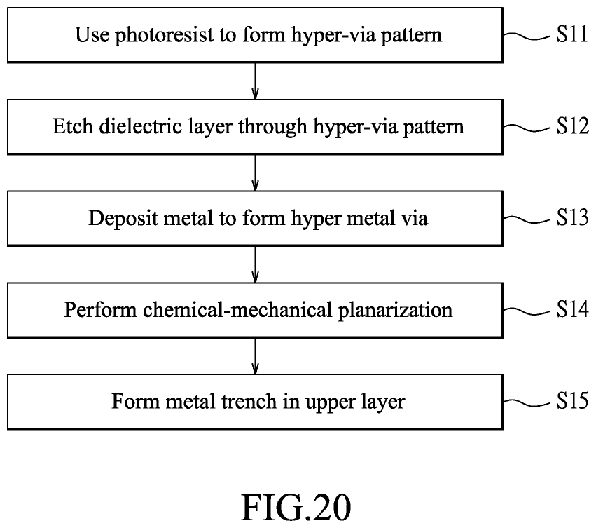

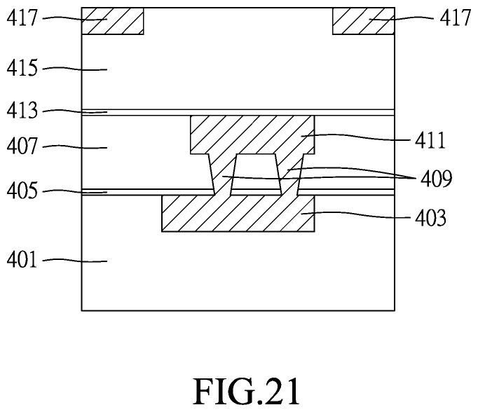

FIG. 20 is a flow chart that cooperates with FIGS. 21 through 26 to illustrate steps of using a single damascene process to form an interconnection structure that includes a hyper metal via according to some embodiments.

In FIG. 21, a first interconnection layer is shown to include a first dielectric layer 401, and a metal trench 403 that is formed in the first dielectric layer 401; a second interconnection layer is disposed immediately over the first interconnection layer with an etch stop layer 405 interposed between the first interconnection layer and the second interconnection layer, and includes a second dielectric layer 407, and multiple regular metal vias 409 and a metal plate 411 that are formed in the second dielectric layer 407; and a third interconnection layer is disposed over the second interconnection layer with an etch stop layer 413 interposed between the second interconnection layer and the third interconnection layer, and includes a third dielectric layer 415, and metal trenches 417 that are formed in the third dielectric layer 415. The regular metal vias 409 extend between the metal plate 411 and the metal trench 403 in the vertical direction, and penetrate the etch stop layer 405, thereby electrically interconnecting the metal plate 411 and the metal trench 403.

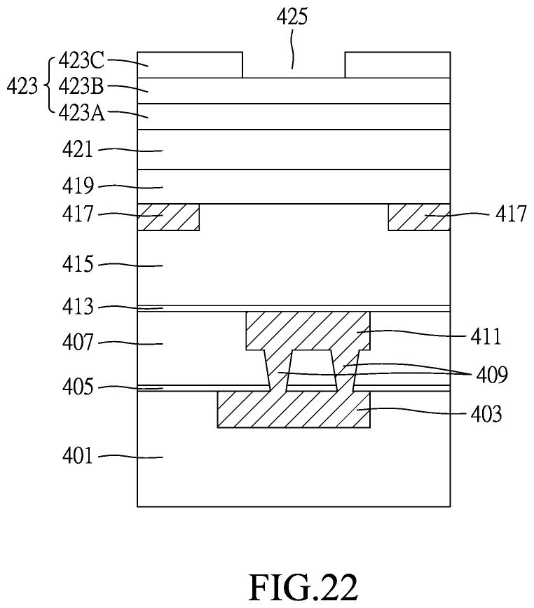

Referring to FIGS. 20 and 22, a capping layer 419, a metal hard mask layer 421, and a tri-layer photoresist 423 are formed over the third dielectric layer 415 and the metal trenches 417 in the given order from bottom to top. The tri-layer photoresist 423 includes a bottom layer 423A (e.g., a lift-off resist layer), a middle layer 423B (e.g., a back anti-reflection coating layer), and a top layer 423C (e.g., a photosensitive layer). The tri-layer photoresist 423 is formed with a hyper-via pattern 425 (step S11). In the illustrative embodiment, a portion of the hyper-via pattern 425 overlaps the metal plate 411 in the vertical direction, and corresponds to a hyper metal via that is to be formed later and connected to the metal plate 411.

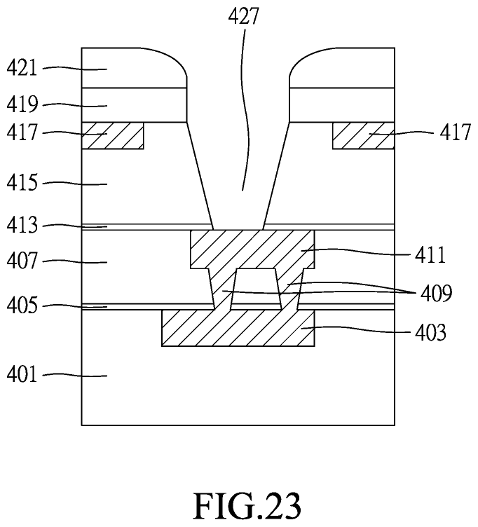

Referring to FIGS. 20 and 23, the metal hard mask layer 421, the capping layer 419, the third dielectric layer 415 and the etch stop layer 413 are etched (step S12) with the tri-layer photoresist 423 that is formed with the hyper-via pattern 425 (see FIG. 22) serving as an etching mask, so as to form a hyper via hole 427 in the third dielectric layer 415, where the metal plate 411 is revealed in the hyper via hole 427.

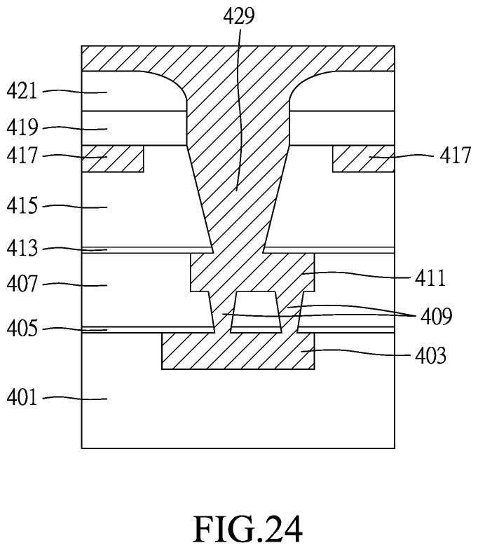

Further referring to FIG. 24, a metal layer is deposited to fill up the hyper via hole 427, thereby forming a hyper metal via 429 in the hyper via hole 427 (step S13). The hyper metal via 427 is connected to the metal plate 411, and penetrates the third dielectric layer 415 of the third interconnection layer from top to bottom.

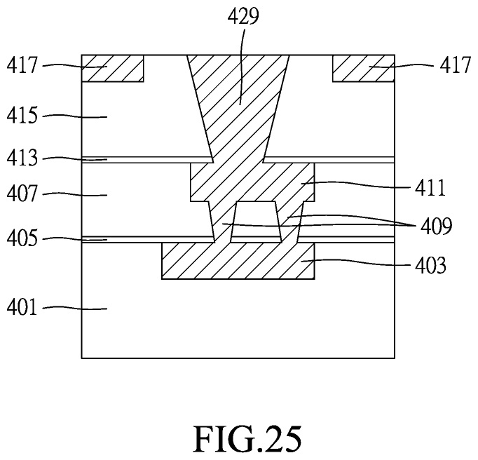

Further referring to FIG. 25, a CMP process is performed (step S14) to remove the metal hard mask layer 421, the capping layer 419 and excessive portions of the metal layer.

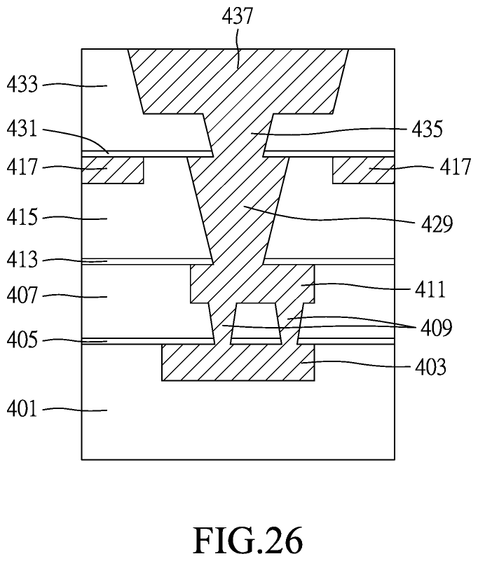

Referring to FIGS. 20 and 26, a fourth interconnection layer is formed over the third interconnection layer (step S15). The fourth interconnection layer includes a fourth dielectric layer 433, and a regular metal via 435 and a metal trench 437 that are formed in the fourth dielectric layer 433. The regular metal via 435 extends between the metal trench 437 and the hyper metal via 429, so the metal trench 437 is electrically connected to the metal trench 403 through the regular metal via 435, the hyper metal via 429, the metal plate 411, and the regular metal vias 409.

In accordance with some embodiments, an interconnection structure is provided to include a substrate, a first dielectric layer disposed over the substrate, a second dielectric layer disposed over the first dielectric layer, a third dielectric layer disposed over the second dielectric layer, and a hyper via. The first dielectric layer is formed with a first metal trench. The second dielectric layer is formed with a metal plate and a connection via. The connection via interconnects the metal plate and the first metal trench. The hyper via penetrates the third dielectric layer and is connected to the metal plate. The hyper via is at least 1.5 times wider than the connection via.

In accordance with some embodiments, the metal plate has an overlapping portion that overlaps the first metal trench in a vertical direction perpendicular to a surface of the substrate, and the connection via extends from the overlapping portion of the metal plate to the first metal trench.

In accordance with some embodiments, the first metal trench has a line portion that extends in a straight line in an extending direction, and a protruding portion that extends laterally from the line portion. The overlapping portion of the metal plate overlaps the protruding portion of the first metal trench, and the connection via extends from the overlapping portion of the metal plate to the protruding portion of the first metal trench.

In accordance with some embodiments, the metal plate has a center deviated from the first metal trench in the vertical direction.

In accordance with some embodiments, the hyper via completely stands on the metal plate.

In accordance with some embodiments, the metal plate has a first length in a first lateral direction, and a second length in a second lateral direction that is perpendicular to the first lateral direction, and each of the first length and the second length is in a range from 40 nm to 150 nm, and a bottom of the hyper via has a width in a range from 10 nm to 60 nm.

In accordance with some embodiments, the first dielectric layer is further formed with a second metal trench, the second metal trench is adjacent to the first metal trench, and a bottom of the hyper via overlaps the second metal trench in a vertical direction perpendicular to a surface of the substrate.

In accordance with some embodiments, the interconnection structure further includes another metal plate that is disposed over and connected to the hyper via, another dielectric layer that is disposed over the another metal plate, and another hyper via that penetrates the another dielectric layer and that is connected to the another metal plate.

In accordance with some embodiments, the hyper via has an aspect ratio in a range from 3 to 6.

In accordance with some embodiments, an angle formed by a side surface of the hyper via and a top surface of the metal plate ranges from 75 degrees to 90 degrees.

In accordance with some embodiments, a top of the hyper via has a width ranging from 40 nm to 150 nm.

In accordance with some embodiments, a bottom of the hyper via has a width ranging from 10 nm to 60 nm.

In accordance with some embodiments, an interconnection structure is provided to include a substrate, a first metal trench disposed over the substrate, a metal plate disposed over and spaced apart from the first metal trench, a connection via extending between the first metal trench and the metal plate, at least one dielectric layer disposed over the metal plate, and a hyper via penetrating the at least one dielectric layer and extending to the metal plate. The hyper via is at least 1.5 times wider than the connection via.

In accordance with some embodiments, the interconnection structure further includes a second metal trench that is adjacent to the first metal trench in a lateral direction parallel to a surface of the substrate. The metal plate overlaps both of the first metal trench and the second metal trench in a vertical direction that is perpendicular to the surface of the substrate.

In accordance with some embodiments, a bottom of the hyper via overlaps the second metal trench in the vertical direction.

In accordance with some embodiments, the hyper via completely stands on the metal plate.

In accordance with some embodiments, the metal plate has an overlapping portion that overlaps the first metal trench in a vertical direction perpendicular to a surface of the substrate, and the connection via extends from the overlapping portion of the metal plate to the first metal trench.

In accordance with some embodiments, the first metal trench has a line portion that extends in a straight line in an extending direction, and a protruding portion that extends laterally from the line portion. The overlapping portion of the metal plate overlaps the protruding portion of the first metal trench, and the connection via extends from the overlapping portion of the metal plate to the protruding portion of the first metal trench.

In accordance with some embodiments, an interconnection structure is provided to include a substrate, a plurality of dielectric layers stacked over the substrate, a hyper via that penetrates at least one of the dielectric layers, a metal plate disposed in one of the dielectric layers, a connection via disposed in said one of the dielectric layers, and a first metal trench disposed in another one of the dielectric layers. The metal plate is connected to a bottom of the hyper via. The connection via is connected to a bottom of the metal plate. The first metal trench is connected to a bottom of the connection via. The hyper via is at least 1.5 times wider than the connection via, and the bottom of the hyper via is wider than the first metal trench.

In accordance with some embodiments, the interconnection structure further includes a second metal trench disposed adjacent to the first metal trench in the another one of the dielectric layers. The bottom of the hyper via overlaps the second metal trench in a vertical direction perpendicular to a surface of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interconnection structure, comprising:
a substrate;
a first dielectric layer that is disposed over the substrate, and that is formed with a first metal trench;
a second dielectric layer that is disposed over the first dielectric layer, and that is formed with a metal plate and a connection via, wherein the connection via interconnects the metal plate and the first metal trench;
a third dielectric layer that is disposed over the second dielectric layer; and
a hyper via that penetrates the third dielectric layer and that is connected to the metal plate;
wherein the hyper via is at least 1.5 times wider than the connection via.

2. The interconnection structure according to claim 1, wherein the metal plate has an overlapping portion that overlaps the first metal trench in a vertical direction perpendicular to a surface of the substrate, and the connection via extends from the overlapping portion of the metal plate to the first metal trench.

3. The interconnection structure according to claim 2, wherein the first metal trench has a line portion that extends in a straight line in an extending direction, and a protruding portion that extends laterally from the line portion; and
wherein the overlapping portion of the metal plate overlaps the protruding portion of the first metal trench, and the connection via extends from the overlapping portion of the metal plate to the protruding portion of the first metal trench.

4. The interconnection structure according to claim 2, wherein the metal plate has a center deviated from the first metal trench in the vertical direction.

5. The interconnection structure according to claim 1, wherein the hyper via completely stands on the metal plate.

6. The interconnection structure according to claim 5, wherein the metal plate has a first length in a first lateral direction, and a second length in a second lateral direction that is perpendicular to the first lateral direction, and each of the first length and the second length is in a range from 40 nm to 150 nm, and a bottom of the hyper via has a width in a range from 10 nm to 60 nm.

7. The interconnection structure according to claim 1, wherein the first dielectric layer is further formed with a second metal trench, the second metal trench is adjacent to the first metal trench, and a bottom of the hyper via overlaps the second metal trench in a vertical direction perpendicular to a surface of the substrate.

8. The interconnection structure according to claim 1, further comprising:
another metal plate that is disposed over and connected to the hyper via;
another dielectric layer that is disposed over the another metal plate; and
another hyper via that penetrates the another dielectric layer and that is connected to the another metal plate.

9. The interconnection structure according to claim 1, wherein the hyper via has an aspect ratio in a range from 3 to 6.

10. The interconnection structure according to claim 9, wherein an angle formed by a side surface of the hyper via and a top surface of the metal plate ranges from 75 degrees to 90 degrees.

11. The interconnection structure according to claim 10, wherein a top of the hyper via has a width ranging from 40 nm to 150 nm.

12. The interconnection structure according to claim 11, wherein a bottom of the hyper via has a width ranging from 10 nm to 60 nm.

13. An interconnection structure, comprising:
a substrate;
a first metal trench disposed over the substrate;
a metal plate disposed over and spaced apart from the first metal trench;
a connection via extending between the first metal trench and the metal plate;
at least one dielectric layer disposed over the metal plate; and
a hyper via penetrating the at least one dielectric layer and extending to the metal plate;
wherein the hyper via is at least 1.5 times wider than the connection via.

14. The interconnection structure according to claim 13, further comprising a second metal trench that is adjacent to the first metal trench in a lateral direction parallel to a surface of the substrate;
wherein the metal plate overlaps both of the first metal trench and the second metal trench in a vertical direction that is perpendicular to the surface of the substrate.

15. The interconnection structure according to claim 14, wherein a bottom of the hyper via overlaps the second metal trench in the vertical direction.

16. The interconnection structure according to claim 15, wherein the hyper via completely stands on the metal plate.

17. The interconnection structure according to claim 13, wherein the metal plate has an overlapping portion that overlaps the first metal trench in a vertical direction perpendicular to a surface of the substrate, and the connection via extends from the overlapping portion of the metal plate to the first metal trench.

18. The interconnection structure according to claim 17, wherein the first metal trench has a line portion that extends in a straight line in an extending direction, and a protruding portion that extends laterally from the line portion;
wherein the overlapping portion of the metal plate overlaps the protruding portion of the first metal trench, and the connection via extends from the overlapping portion of the metal plate to the protruding portion of the first metal trench.

19. An interconnection structure, comprising:
a substrate;
a plurality of dielectric layers that are stacked over the substrate;
a hyper via that penetrates at least one of the dielectric layers;
a metal plate that is disposed in one of the dielectric layers, and that is connected to a bottom of the hyper via;
a connection via that is disposed in said one of the dielectric layers, and that is connected to a bottom of the metal plate; and
a first metal trench that is disposed in another one of the dielectric layers, and that is connected to a bottom of the connection via;
wherein the hyper via is at least 1.5 times wider than the connection via, and the bottom of the hyper via is wider than the first metal trench.

20. The interconnection structure according to claim 19, further comprising a second metal trench disposed adjacent to the first metal trench in the another one of the dielectric layers;
wherein the bottom of the hyper via overlaps the second metal trench in a vertical direction perpendicular to a surface of the substrate.
